(19) United States
(12) Patent Application Publication
(10) Pub. No.: US 2025/0348644 A1
(43) Pub. Date: Nov. 13, 2025

(54) METHODS AND SYSTEMS FOR DETECTING FUNCTIONAL DEFECTS AT DESIGNING STAGE OF A DESIGN CODE

(71) Applicant: Samsung Electronics Co., Ltd., Suwon-si (KR)

(72) Inventors: Maruthi Srinivas NARASIMHAN, Bengaluru (IN); Satyam SAXENA, Bengaluru (IN)

(73) Assignee: Samsung Electronics Co., Ltd., Suwon-si (KR)

(21) Appl. No.: 18/764,512

(22) Filed: Jul. 5, 2024

(30) Foreign Application Priority Data
May 13, 2024 (IN) 202441037422

(51) Int. Cl. G06F 30/33; G06F 30/327

(52) U.S. Cl. CPC G06F 30/33; G06F 30/327

(57) ABSTRACT

A method for detecting one or more functional defects in a design code includes generating, using processing circuitry, Hardware Verification Language (HVL) code representing semantic behaviour of design code, the generating including identifying one or more expressions associated with the one or more functional defects in the HVL code, identifying, using the processing circuitry, one or more patterns associated with the one or more functional defects in one or more second design code written in the first language, mapping, using the processing circuitry, the one or more expressions of the HVL code with the one or more identified patterns, forming, using the processing circuitry, a bind of the one or more expressions with the one or more patterns based on the mapping, and evaluating, using the processing circuitry, the bind to identify the one or more functional defects in the design code.

### CROSS-REFERENCE TO RELATED APPLICATION

This U.S. non-provisional application claims the benefit of priority under 35 U.S.C. 119 from Indian Patent Application number 202441037422, filed on May 13, 2024 in the Indian Intellectual Property Office, the entire contents of which are herein incorporated by reference.

### BACKGROUND

Various example embodiments of the inventive concepts relate, in general, to the field of design code. Particularly, but not exclusively, the one or more of the example embodiments relate to a method, non-transitory computer readable medium, apparatus, and/or system for detecting functional defects in a design code.

Functional defects in design code are issues or flaws within the software and/or hardware system's codebase that cause the system to behave incorrectly or unexpectedly. These defects may arise due to various reasons, including errors in the logic, design flaws, and/or incorrect implementation of requirements. For example, a banking application might have a functional defect where it fails to calculate interest correctly, resulting in financial inaccuracies for users. Similarly, a hardware system might have a defect where certain inputs lead to unexpected outputs and/or behaviour, causing disruptions in its intended operation. One common type of functional defect is incorrect behaviour, where the system does not perform the intended function as specified in the requirements. Additional categories of functional defects include unexpected behaviour, missing functionality, inconsistent behaviour, etc. Finally, functional defects may also encompass security vulnerabilities, where flaws in the design code expose the system to potential security risks. These vulnerabilities may range from simple authorization bypasses to complex injection attacks, compromising the integrity, confidentiality, and/or availability of the system and/or its data.

Detecting functional defects in software and hardware systems, therefore, becomes critical to ensure reliability, customer satisfaction, and cost-effectiveness. Early detection helps decrease and/or prevent system failures, reducing downtime and data loss while enhancing user trust. Addressing defects before deployment decreases and/or minimizes rework expenses and ensures compliance with regulatory standards. Additionally, detecting defects early improves system performance, improving and/or optimizing resource utilization and response times. Furthermore, mitigating functional defects enhances security by reducing vulnerabilities and protecting sensitive data. Overall, timely detection of functional defects is essential for delivering high-quality, reliable, and secure software and hardware products that meet user expectations and industry standards.

In the existing scenario, detecting functional defects in software and/or hardware systems poses several challenges. Firstly, the complexity of modern systems makes it difficult to identify all possible failure scenarios. Additionally, functional defects may only manifest under specific conditions, making them elusive during testing. Limited resources and time constraints further hinder thorough defect detection efforts. Furthermore, the dynamic nature of software and/or hardware interactions complicates defect identification, requiring comprehensive testing across various environments. Moreover, legacy systems may lack adequate documentation and/or testing frameworks, impeding defect detection and resolution. Lastly, the interdisciplinary nature of defect detection necessitates collaboration between developers, testers, and domain experts, which can introduce communication barriers and coordination challenges.

The information disclosed in this background of the disclosure section is only for the enhancement of understanding of the general background of the inventive concepts and should not be taken as an acknowledgement or any form of suggestion that this information forms the prior art already known to a person skilled in the art.

### SUMMARY

In at least one example embodiment of the inventive concepts, a method for detecting one or more functional defects in a design code is disclosed. The method includes generating, using processing circuitry, Hardware Verification Language (HVL) code representing semantic behaviour of the design code, the design code written in a first language different than a second language used to generate the HVL code, the generating including identifying one or more expressions associated with the one or more functional defects in the HVL code, identifying, using the processing circuitry, one or more patterns associated with the one or more functional defects in one or more second design code written in the first language, mapping, using the processing circuitry, the one or more expressions of the HVL code with the one or more identified patterns, forming, using the processing circuitry, a bind of the one or more expressions with the one or more patterns based on the mapping, the bind including one or more semantic expressions of a combination of the one or more expressions and the one or more patterns, and evaluating, using the processing circuitry, the bind to identify the one or more functional defects in the design code.

In at least one example embodiment of the inventive concepts, the one or more patterns are identified in the one or more second design code using at least a Python framework based on the generated HVL code.

In at least one example embodiment of the inventive concepts, the evaluating the bind further comprises: identifying one or more performance parameters associated with the semantic expressions, and detecting the one or more functional defects based on the one or more identified performance parameters and one or more threshold performance parameters corresponding to the semantic expressions.

In at least one example embodiment of the inventive concepts, the threshold performance parameter is calculated using the one or more patterns.

In at least one example embodiment of the inventive concepts, a system for detecting one or more functional defects in a design code is disclosed. The system comprises memory and processing circuitry coupled to the memory. The processing circuitry is configured to generate Hardware Verification Language (HVL) code representing semantic behaviour of a first design code, the design code written in a first language different than a second language used to generate the HVL code, the generating including identifying one or more expressions associated with the one or more functional defects in the HVL code, identify one or more patterns associated with the one or more functional defects in one or more second design code written in the first language, map the one or more expressions of the HVL code with the one or more identified patterns, form a bind of the one or more expressions and the one or more patterns based on the mapping, the bind including one or more semantic expressions of a combination of the one or more expressions and the one or more patterns, and evaluate the bind to identify the one or more functional defects in the design code.

In at least one example embodiment of the inventive concepts, a non-transitory computer-readable medium comprising computer-readable instructions recorded thereon, which when executed by processing circuitry, causes the processing circuitry to generate Hardware Verification Language (HVL) code representing semantic behaviour of the design code, the design code written in a first language different than a second language used to generate the HVL code, the generating including identifying one or more expressions associated with the one or more functional defects in the HVL code; identify one or more patterns associated with the one or more functional defects in one or more second design code written in the first language and then mapping, using the processing circuitry, the one or more expressions of the HVL code with the one or more identified patterns; form a bind of the one or more expressions with the one or more patterns based on the mapping, the bind including one or more semantic expressions of a combination of the one or more expressions and the one or more patterns; and evaluate the bind to identify the one or more functional defects in the design code.

The foregoing summary is illustrative only and is not intended to be in any way limiting. In addition to the illustrative example embodiments and features described above, further example embodiments and features will become apparent by reference to the drawings and the following detailed description.

### BRIEF DESCRIPTION OF THE DRAWINGS

Some aspects of the example embodiments described herein may provide a method, non-transitory computer readable medium, apparatus, and/or system for detecting functional defects at the designing stage of a design code model.

The accompanying drawings, which are incorporated in and comprise a part of this disclosure, illustrate various example embodiments and, together with the description, serve to explain the disclosed inventive concepts. The same numbers are used throughout the figures to reference like features and components. Some example embodiments of devices, systems, non-transitory computer readable media, and/or methods in accordance with one or more example embodiments of the inventive concepts are now described, by way of example only, and with reference to the accompanying figures, in which:

FIG. 1 illustrates a schematic representation of system for detecting functional defects in a design code, in accordance with at least one example embodiment of the inventive concepts;

FIG. 2 illustrates an example of array bit slicing overflow condition, in accordance with at least one example embodiment of the inventive concepts;

FIG. 3 depicts a flow chart 300 illustrating a non-limiting method for fixing an array bit slicing overflow condition in accordance with at least one example embodiment of the inventive concepts; and

FIG. 4 illustrates a flow chart depicting a method of detecting one or more functional defects in the design code, in accordance with at least one example embodiment of the inventive concepts.

### DETAILED DESCRIPTION

While various example embodiments of the inventive concepts are susceptible to various modifications and alternative forms, specific example embodiment thereof has been shown by way of example in the drawings and will be described in detail below. It should be understood, however that it is not intended to limit the disclosure to the particular forms disclosed, but on the contrary, the inventive concepts are to cover all modifications, equivalents, and alternative falling within the spirit and the scope of the example embodiments.

The terms “comprises”, “comprising”, or any other variations thereof, are intended to cover a non-exclusive inclusion, such that a system, device, non-transitory computer readable medium, and/or method that comprises a list of components and/or operations does not include only those components and/or operations but may include other components and/or operations not expressly listed or inherent to such system, device, non-transitory computer readable medium, and/or method. In other words, one or more elements in a device, system, non-transitory computer readable medium, method, and/or apparatus proceeded by “comprises . . . a” does not, without more constraints, preclude the existence of other elements and/or additional elements in the device, system, non-transitory computer readable medium, method, and/or apparatus.

The term “unit”, “module” and “design block” have been used interchangeably herein.

In the following detailed description of various example embodiments of the inventive concepts, reference is made to the accompanying drawings that form a part hereof, and in which are shown by way of illustration specific example embodiments in which the inventive concepts may be practiced. These example embodiments are described in sufficient detail to enable those skilled in the art to practice the inventive concepts, and it is to be understood that other example embodiments may be utilized and that changes may be made without departing from the scope of the inventive concepts. The following description is, therefore, not to be taken in a limiting sense.

One or more example embodiments of the inventive concepts address the challenges of system complexity by allowing a more systematic examination of potential failure scenarios, mitigating the risk of overlooking critical defects and facilitating a more reliable and robust technique for detecting functional defects in design code.

In addition, when a bit slicing operation on an array is performed, specific bits are extracted from each element. Depending on the size of the extracted bits, data may be lost. For example, if only a few bits are extracted from each element, the resulting values may not accurately represent the original data.

One or more example embodiments of the inventive concepts address the above challenges by proposing a method, non-transitory computer readable medium, device, and/or system for detecting functional defects in a design code.

The various example embodiments of the inventive concepts aim to overcome the limitations of existing analysis tools through automation with, for example, Python, etc., for identifying expressions and/or Hardware Description Language (HDL) signals that reduces potential for human error.

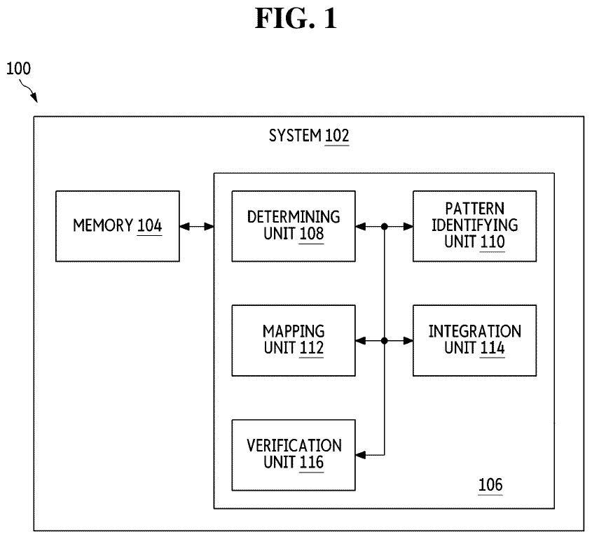

FIG. 1 illustrates a schematic representation 100 of a system 102 for detecting functional defects in a design code, in accordance with at least one example embodiment of the inventive concepts. The system 102 includes a memory 104 and processing circuitry 106, but is not limited thereto, and for example, may include a greater or lesser number of constituent components. Further, the processing circuitry 106 may include a determining unit 108 (e.g., determining circuitry, etc.), a pattern identifying unit 110 (e.g., pattern identifying circuitry, etc.), a mapping unit 112 (e.g., mapping circuitry, etc.), a verification unit 116 (e.g., verification circuitry, etc.), and/or an integration unit 114 (e.g., integration circuitry, etc.), etc. Processing circuitry 106 may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto. The components of the system 102 are coupled to each other and interact with each other for detecting the one or more functional defects in the design code.

In general, functional defects (e.g., bugs, errors, undesired behavior, etc.) in a Hardware Verification Language (HVL) code (e.g., HVL software, etc.) refer to issues and/or errors that may impact the proper function and/or correctness of a hardware design. HVL code is used for verifying and/or testing hardware designs, ensuring that the hardware designs perform as expected. Identifying and addressing functional defects in the HVL code is crucial for improving and/or guaranteeing the reliability, and/or accuracy of the hardware design. In at least one example embodiment, functional defects that occur in the HVL code includes, but is not limited to, Array Indexing Out of Bounds, data overflow, uninitialized variables, and the like.

The determining unit 108 (e.g., determining circuitry, etc.) may be configured to determine and/or generate (e.g., write, output, produce, etc.) a Hardware Verification Language (HVL) code representing semantic behaviour of a design code (e.g., code written in a design language different from the HVL, such as HDL, etc.). In general, semantic behaviour relates to understanding intended meaning and interpretation of actions and/or expressions in a code. Semantic behaviour is an aspect of programming, linguistics, artificial intelligence (AI), and other fields where communication and interpretation play a central role. Understanding the semantic behaviour is desired and/or essential for creating accurate, reliable, and/or meaningful solutions. The design code may refer to code written in a hardware design language (e.g., a first language), etc., but is not limited thereto. In general, HVL code is code generated and/or written in a verification language, e.g., a second language, and the HVL code is used for verifying and/or testing the hardware design(s) embodied by the HDL code, etc. The HVL code is determined to check for the correctness of the hardware designs of the HDL code to determine whether the hardware designs, e.g., the HDL code, perform as expected and/or desired.

In at least one example embodiment, the HVL code identifies one or more expressions associated with functional defects (e.g., bugs, design defects, etc.) in the HVL code. As discussed above, the functional defects include, but are not limited to, array indexing out of bound, etc. In general, array indexing out of bound is a condition that occurs when a program tries to access an array element that is beyond a declared array size. This condition further leads to overflow issues (e.g., memory overflow issues, etc.) and/or may be exploited by malicious code and/or malicious actors.

Further, the pattern identifying unit 110 (e.g., pattern identifying circuitry, etc.) may be configured to identify one or more patterns associated with functional defects in stored design code written in at least one of: Hardware Description Language (HDL), System Verilog, and/or Register-Transfer Level (RTL), etc., but the example embodiments are not limited thereto. In at least one example embodiment, the one or more patterns are desired and/or pre-existing patterns identified using one or more past sets of data associated with the HVL code. In an example, more than 40 unique patterns exist in the latest projects, but the example embodiments are not limited thereto, and the number of unique patterns may be greater or less than 40. The past set of data associated with the HVL code may be inputted to the pattern identifying unit 110 to identify the one or more patterns. In at least one example embodiment, the one or more patterns may correspond to expressions associated with the functional defects previously identified in earlier HVL code and/or design projects, etc. In at least one example embodiment, the one or more patterns are identified using a Python framework, but the example embodiments are not limited thereto, and other programming and/or scripting languages may be implemented.

In at least one example embodiment, the mapping unit 112 (e.g., mapping circuitry, etc.) may be configured to map the one or more expressions of the HVL code with the one or more patterns. Based on the mapping, the integration unit 114 integrates the one or more expressions with the one or more patterns to form a bind (e.g., link) of the one or more expressions and the one or more patterns. The bind comprises semantic expressions of (and/or corresponding to, associated with, etc.) a combination of the one or more expressions and the one or more patterns. In at least one non-limiting example embodiment, the bind may refer to attaching a given module/unit to another module/unit in the given system.

Further, the bind is evaluated to determine the functional defects. The bind is evaluated using the verification unit 116 (e.g., verification circuitry, verification tool, etc.). In at least one example embodiment, the verification unit 116 takes as input code and/or software corresponding to the design to be tested, e.g., the HVL code, RTL code, HDL code, etc., along with the bind with all of the semantic expressions associated with the design. The input code and bind are then evaluated. Based on the evaluation, a number of assertions are created and/or generated, etc. Further, each assertion is evaluated, and if the assertion is proven as true, there is no functional defect detected for the HVL code. If the assertion is proven as false, then the verification unit 116 generates at least one testcase including at least one pattern of failure which may identify a root case and/or identify the functional defects (e.g., errors, bugs, undesired performance, etc., by the code and/or design), etc., but is not limited thereto. Upon receiving the HDL RTL fixes, the same assertion is again functionally evaluated by the formal verification unit 116.

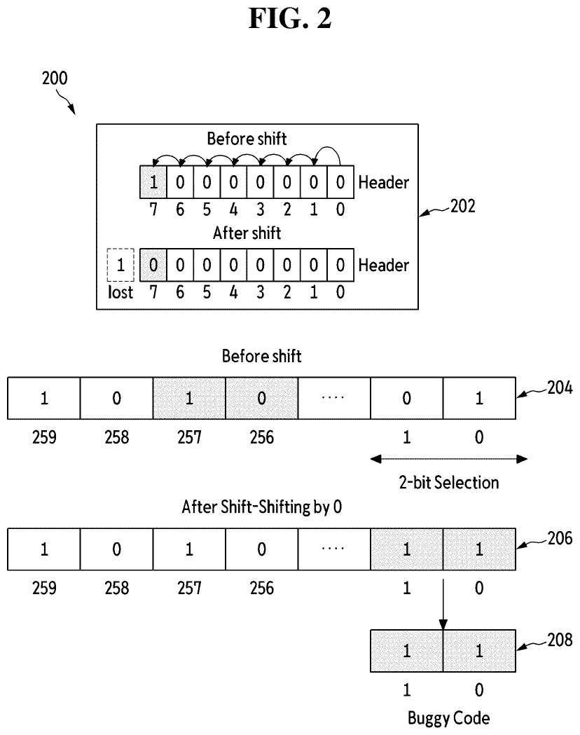

For example, one or more expressions may be represented as shown below:
sliced data[1:0]<=i_data packet [259:0]>>({header [31:24]}<<N)

Wherein i_data packet [259:0] represents a data packet with a length of 260 bits as shown in FIG. 2; header [31:24] represents an 8-bit header for the data packet contained in bits 24 to 31 of the i_data packet of FIG. 2; and sliced data[1:0] represents data bits, e.g., bits 0 and 1 of the data packet of FIG. 2, to be sliced from the i_data packet. However, the example embodiments are not limited thereto, and other expressions may be used and/or other bits/number of bits may be used to represent the sliced data, the data packet, and/or the header of the data packet, etc.

The verification unit 116 may be configured to identify at least one performance parameter (e.g., desired performance criteria and/or metrics associated with the design and/or design code, etc.) of the semantic expressions. Further, the verification unit 116 may be configured to detect the one or more functional defects (e.g., errors, bugs, etc.) if the performance parameter of the semantic expressions is below a threshold performance parameter corresponding to and/or associated with the semantic expressions (e.g., a desired threshold performance parameter, etc.), wherein the threshold performance parameter may be configured and/or set by a user, etc. The threshold performance parameter is calculated using and/or based on the one or more patterns.

The processing circuitry 106 may be embodied as a multi-core processor, a single core processor, or a combination of one or more multi-core processors and one or more single core processors. For example, the processing circuitry 106 may be embodied as one or more of various processing devices, such as a coprocessor, a microprocessor, a controller, a digital signal processor (DSP), a processing circuitry with or without an accompanying DSP, or various other processing devices including, a microcontroller unit (MCU), a hardware accelerator, a special-purpose computer chip, or the like.

In at least one example embodiment, the memory 104 is capable of storing machine executable instructions (e.g., computer readable instructions, etc.). In at least one example embodiment, the processing circuitry 106 is embodied as an executor of software instructions. As such, the processing circuitry 106 is capable of executing special purpose instructions stored in the memory 104 to perform one or more operations of the methods described below, thereby transforming the processing circuitry 106 into special purpose processing circuitry (e.g., a special purpose processor, etc.).

The memory 104 may be any type of storage accessible to the processing circuitry 106 to perform respective functionalities, as explained in detail with reference to FIGS. 1 to 4. For example, the memory 104 may include one or more volatile or non-volatile memories, or a combination thereof. In addition, the memory 104 may be embodied as semiconductor memories, such as flash memory, mask ROM, PROM (programmable ROM), EPROM (erasable PROM), RAM (random access memory), and the like.

It shall be noted that, in some example embodiments, the system 102 may include more or fewer components than those depicted herein. The various components of the system 102 may be implemented using hardware and/or a combination of hardware and software and/or firmware, etc. Further, the various components of the system 102 may be operably coupled with each other. More specifically, various components of the system 102 may be capable of communicating with each other using communication channel media (such as buses, interconnects, etc.).

FIG. 2 illustrates an example of an array bit slicing overflow condition, in accordance with at least one example embodiment of the inventive concepts. In this, a non-limiting example scenario has been illustrated where at operation 202, a header including an 8-bit array with an index of 0 to 7 may be considered (e.g., which may correspond to the bits [31:24] of a data packet (e.g., i_data packet as discussed above), but the example embodiments are not limited thereto. The header (e.g., the 8-bit array) may correspond to a sequence of bits of a larger array (e.g., the 260-bit array 204), such as the data packet i_data packet discussed above, wherein the header contains information about the larger array (e.g., the i_data packet), etc., but the example embodiments are not limited thereto. During a left bit shift operation, the most significant bit (MSB) (e.g., the left-most bit in FIG. 2) of the header is lost, and the code using and/or associated with the array becomes buggy code, for instance, the code may have a functional defect, etc. To elaborate, initially, the code may perform a left shift operation on the header and associated data, e.g., the larger array 204. The left shift operation may be performed on N bits, where the value of N has been taken as 1 in an example scenario. However, after this shift, the header and data bits may be misaligned due to the leftward movement, potentially causing data loss and/or corruption, as illustrated at operation 202 of FIG. 2 leading to the loss of the MSB.

At operation 204, following the left shift, the code may intend to perform a right shift operation based on certain conditions which may be potentially determined by the header data. However, due to incorrect logic and/or misinterpretation, the right shift operation may not correctly align with the left shift performed at operation 202, or in other words, while it is expected that the data stored in the header after performing both the left shift operation and the right shift operation is the same as the data stored in the header before performing the left shift operation (e.g., the original data stored in the header), the header data is different (e.g., not equal, not the same, etc.) due to the MSB being lost after the left shift operation. As a result, the right shift may not appropriately account for the changes made during the left shift, leading to further misalignment and/or corruption of data. However, the example embodiments are not limited thereto, and for example, a similar error may potentially occur with respect to the loss of a least significant bit (LSB) after the performance of a right shift operation and then a left shift operation, etc.

As evident at operation 206, the misalignment and incorrect shifting operations may result in unexpected outcomes, such as the loss and/or corruption of header information and/or misalignment of subsequent data, etc. The code may eventually fail to properly preserve and manipulate the data as intended, leading to errors in processing and generating buggy output 208. The generated buggy code 208 may therefore be due to inconsistencies and/or errors in the shifting logic between at operations 202 to 206 leading to misalignment, loss, and/or corruption of data during the shifting process and it may ultimately lead to cascading effect on the functionality of the code as explained in the upcoming paragraphs.

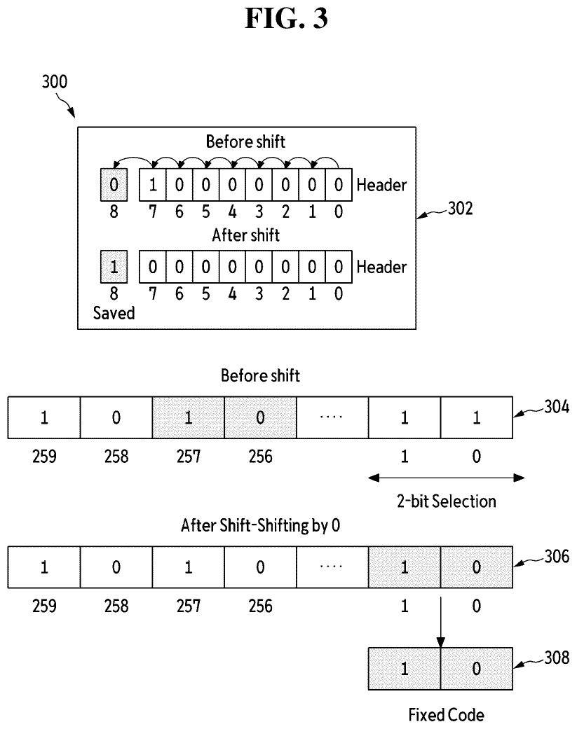

If the MSB is not saved, then the subsequent shifting operation, typically a right shift, occurs with a value of 2*p. Here, p may refer to the value stored in bits [31:24] of the header, in at least one example embodiment. This value may determine the amount by which the data should be shifted. For example, as shown in FIG. 2, since the header stores 00000000 after the left shift operation, the subsequent shifting operation (e.g., the right shift operation) is shifted by 0 bits, thus the value of bits [1:0] of the i_data packet remain “1” and “1” as shown in operation 206. Since the MSB is not saved, there is no special handling required for bits 257 and bit 256 during the shifting operation. These bits may therefore be shifted along with the rest of the data without any specific adjustments. Thus, the failure to save the MSB and properly handle the shifting operation may contribute to the generation of buggy code 208. Data loss, misalignment, and/or corruption resulting from the absence of the MSB may lead to erroneous outcomes in the code thus giving rise to defects in code and degrading its functionality. However, by saving the MSB at operation 202, the generation of buggy codes may be avoided as discussed in the upcoming paragraphs in conjunction with FIG. 3.

FIG. 3 depicts an example method for fixing an array bit slicing overflow condition in accordance with at least one example embodiment of the inventive concepts. As shown in FIG. 3, at operation 302, the MSB of the header is preserved and/or saved in memory, ensuring that critical information may be retained. The header of the 8-bit array corresponds to a sequence of bits at the beginning of the array that contains information about the array itself, etc. As illustrated in the example scenario at operation 302, each bit may be shifted left by 1 to get the value 2*p, where p is the value stored in a header of the 8-bit array. After the bit shift operation, the most significant bit is saved in an additional bit (e.g., bit 8), and the code may be fixed.

Then at operation 304, with the saved MSB at operation 302, the right shift operation may proceed accurately. In another example, if the value of p is 128 (e.g., 1000000 in binary, or in other words, the value of the data stored in the header 302), then the value of 2*p is 256. Thus, after the left shift operation, the MSB may be saved in and/or represented by bit 257, and bit 256 may represent the subsequent bit. During the right shift operation, bit 257 and bit 256 are right shifted to index 7 and 6 of the header, e.g., bits [7:6] of the i_data packet in operation 306, respectively, as intended. Because the bits have been shifted correctly, the value of 2*p are correct, thereby maintaining proper alignment of the data.

In the example scenario illustrated in FIG. 3, it is assumed that the original header before the left shift operation is 10000000 (e.g., bits 7 to 0 of the header shown in FIG. 3). After the left shift operation, the header becomes 00000000, with the MSB (e.g., 1) being preserved in a separate bit of memory, e.g., bit 8. During the subsequent right shift operation, bit 257 (representing the MSB) and bit 256 (the current MSB) are shifted to index 1 and 0, e.g., bits [1:0] of the i_data packet, respectively, based on the value of 2*p. Therefore, by saving the previous MSB value and properly handling the shifting operation, the fixed code may ensure the data integrity and alignment throughout the process. This may subsequently decrease and/or prevent data loss, corruption, and/or misalignment, ensuring that the shifted data accurately reflects the original input. The same process can be explained with the help of working flow in the following paragraphs.

In conjunction with FIG. 3, a first operation may be associated with saving the value of at least one data packet, e.g., i_data packet, which may represent, for example, incoming data packet and/or input data, etc., but the example embodiments are not limited thereto and other forms of data may be used. Then it may save the value of a header associated with and/or corresponding to the at least one data packet, wherein the header may represent a specific portion of the data packet, and the value of N, which may be a numerical value (e.g., N=1 in FIG. 3, but is not limited thereto), where the values of these above defined variables (e.g., i_data_packet, header value, the value of N, etc.) may be saved for later use.

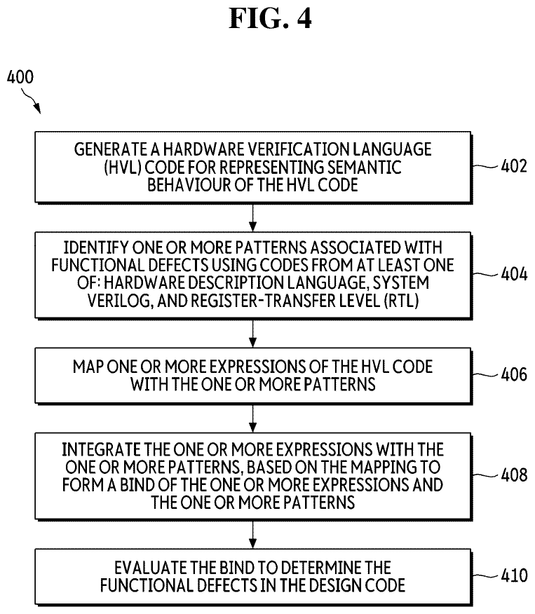

Then the saved “header value” and saved “value of N” from the previous operation may be multiplied and the result of the multiplication may be stored in the same location of header value. This operation may be read in conjunction with the operation 402 of FIG. 4. Thus, the multiplication operation described in the provided operations may be part of the process of generating and/or simulating the semantic behavior of the HVL code, as per various example embodiments of the inventive concepts. This updated header value may act as an index value from which a bit may be sliced in the upcoming operation.

Subsequently, in operation 404, the sliced data may be calculated by extracting the slice of bits starting with the index as calculated by the above multiplication performed in the previous operation, e.g., the results of operation 402. Thus, the extraction of sliced data from the i_data_packet based on the updated header value aligns with the identification of patterns associated with functional defects, as described in the foregoing paragraphs. Then the obtained sliced data may be compared to that of modules of the design (e.g., design code, etc.) in a verification operation and/or verification stage, etc. This operation may be read in conjunction with operations 406-410 of FIG. 4. Thus, the comparison of the sliced data to a module of a design code in verification aligns with the evaluation of the bind to identify functional defects in the design code, as described in the provided paragraphs.

To summarize, these 4 operations depicted in combination of the illustrations of FIGS. 3 and 4 outline a methodological approach for analysing and verifying design code using Hardware Verification Language (HVL) code, with the ultimate goal of detecting and correcting functional defects associated with the design code, in accordance with the one or more example embodiments of the inventive concepts. In view of this, FIG. 4 may be further elaborated in the forthcoming paragraphs.

FIG. 4 illustrates a flow chart depicting a method 400 for detecting one or more functional defects in the design code, in accordance with at least one example embodiment of the inventive concepts. The method 400 is explained in view of FIG. 1, but the example embodiments are not limited thereto.

The method 400 includes operations performed using the system 102 of FIG. 1, but is not limited thereto. For example, the operations of the method 400 are described herein as being performed by the processing circuitry 106 of the system 102, however, the example embodiments are not limited thereto, and for example, the operations of the method 400 may be practiced using one or more processors of a system 102 other than the processing circuitry 106, etc. To describe the method 400, the same reference numerals are used as used in FIGS. 1 to 3. The method 400 starts at operation 402.

At operation 402, the method 400 includes determining (e.g., generating, etc.) the HVL code for determining (and/or simulating, etc.) semantic behavior of the HVL code. The HVL code is determined and/or generated using the determining unit 108 based on design code written in a different software language (e.g., HDL language, etc.), but the example embodiments are not limited thereto. The determining unit 108 may be configured to determine and/or generate the Hardware Verification Language (HVL) code (e.g., written in a second language) for representing semantic behaviour based on a design and/or design code of a desired design project (e.g., code written in a first language). The design code may refer to code written in a hardware design language, etc., but is not limited thereto. In at least one example embodiment, the HVL code identifies one or more expressions associated with functional defects in the HVL code, and thereby identify and/or detect functional defects in the HDL code, etc. The functional defects include but are not limited to array indexing out of bound, etc.

At operation 404, the method 400 includes identifying the one or more patterns associated with the functional defects using design code from at least one of: HDL, System Verilog, and RTL, etc., but the example embodiments are not limited thereto, and other languages may be used for the patterns and/or design code. The one or more patterns are identified using the pattern identification unit 110, but is not limited thereto. The pattern identifying unit 110 may be configured to identify one or more patterns associated with the functional defects using design codes from at least one of: HDL, System Verilog, and RTL, etc., but is not limited thereto and other languages may be used for the patterns and/or design codes. In at least one example embodiment, the one or more patterns are desired and/or pre-existing patterns identified using past sets of data associated with the HVL code, etc. The past set of data associated with the HVL code may be inputted to the pattern identifying unit 110 to identify the one or more patterns. In at least one example embodiment, the one or more patterns may correspond to expressions associated with functional defects, etc.

At operation 406, the method 400 includes mapping of the one or more expressions of the HVL code with the one or more patterns, using the mapping unit 112, but is not limited thereto.

At operation 408, the method 400 includes integrating the one or more expressions with the one or more patterns, based on the mapping to form a bind of the one or more expressions and the one or more patterns. In at least one example embodiment, the mapping unit 112 may be configured to map the one or more expressions of the HVL code with the one or more patterns. Based on the mapping, the integration unit 114 integrates the one or more expressions with the one or more patterns to form a bind of the one or more expressions and the one or more patterns, but is not limited thereto. The bind comprises a combination of semantic expressions of the one or more expressions and the one or more patterns, etc.

At operation 410, the method 400 includes evaluating the bind to determine the functional defects in the design code, or in other words, the system 100 may analyze the HVL code based on the bind to identify any functional defects associated with the design code. Additionally, the system 100 may correct, fix, repair, etc., the identified functional defects in HVL code based on the results of the evaluation of the bind.

The method 400 provides various advantages and/or benefits. The method 400 catches and/or identifies one or more bugs, errors, defects, and/or undesired behavior, etc. in the design code efficiently and may be applied to any design code. Unlike dynamic verification, the method 400 does not require any test bench implementations. The method 400 may be applied early in design project cycles to identify design issues to improve and/or enhance design release quality. Additionally, the identified bugs, errors, defect, and/or undesired behavior, etc., in the design code may be corrected, fixed, repaired, improved, etc., based on the results of the method 400.

The disclosed method 300 of FIG. 3 and/or the method 400 of FIG. 4, and/or one or more operations of the methods 300 and 400 may be implemented using software including special purpose computer-executable instructions stored on one or more non-transitory computer-readable media (e.g., one or more optical media discs, volatile memory components (e.g., DRAM and/or SRAM, etc.), and/or non-volatile memory and/or storage components (e.g., hard drives and/or solid-state non-volatile memory components, such as Flash memory components, etc.) and executed on a computer (e.g., any suitable computer, such as a laptop computer, net book, Web book, tablet computing device, smart phone, or other mobile computing device). Such special purpose software may be executed, for example, on a single local computer. However, the example embodiments are not limited thereto, and for example, the methods and/or method operations may be implemented using logic gates, special purpose processing circuitry, etc., implementing one or more of the example embodiments.

It will be understood by those of ordinary skill in the art that the terms used herein are generally intended as “open” terms (e.g., the term “including” should be interpreted as “including but not limited to,” the term “having” should be interpreted as “having at least,” the term “includes” should be interpreted as “includes but is not limited to,” etc.). For example, as an aid to understanding, the detailed description may contain usage of the introductory phrases “at least one” and “one or more” to introduce recitations. However, the use of such phrases should not be construed to imply that the introduction of a recitation by the indefinite articles “a” or “an” limits any particular part of description containing such introduced recitation to example embodiments of the inventive concepts containing only one such recitation, even when the introductory phrases “one or more” or “at least one” and indefinite articles such as “a” or “an” (e.g., “a” and/or “an” should typically be interpreted to mean “at least one” or “one or more”) are included in the recitations; the same holds true for the use of definite articles used to introduce such recitations. In addition, even if a specific part of the introduced description recitation is explicitly recited, those of ordinary skill in the art will recognize that such recitation should typically be interpreted to mean at least the recited number (e.g., the bare recitation of “two recitations,” without other modifiers, typically means at least two recitations or two or more recitations).

While various example embodiments of the inventive concepts have been disclosed herein, other example embodiments will be apparent to those skilled in the art. The various example embodiments disclosed herein are for purposes of illustration and are not intended to be limiting, with the true scope and spirit being indicated by the following detailed description.

We claim:

1. A method for detecting one or more functional defects in a design code, the method comprising:
generating Hardware Verification Language (HVL) code representing semantic behaviour of the design code, the design code written in a first language different than a second language used to generate the HVL code, the generating including identifying one or more expressions associated with the one or more functional defects in the HVL code;
identifying one or more patterns associated with the one or more functional defects in one or more second design code written in the first language;
mapping the one or more expressions of the HVL code with the one or more identified patterns;
forming a bind of the one or more expressions with the one or more patterns based on the mapping, the bind including one or more semantic expressions of a combination of the one or more expressions and the one or more patterns; and
evaluating the bind to identify the one or more functional defects in the design code.

2. The method as claimed in claim 1, wherein the one or more patterns are identified in the one or more second design code using at least a Python framework based on the generated HVL code.

3. The method as claimed in claim 1, wherein the evaluating the bind further comprises:
identifying one or more performance parameters associated with the semantic expressions; and
detecting the one or more functional defects based on the one or more identified performance parameters and one or more threshold performance parameters corresponding to the semantic expressions.

4. The method as claimed in claim 3, wherein the one or more threshold performance parameters are calculated using the one or more patterns.

5. A system for detecting one or more functional defects in a design code, the system comprising:
memory;
processing circuitry coupled to the memory, wherein the processing circuitry is configured to:
generate Hardware Verification Language (HVL) code representing semantic behaviour of a first design code, the design code written in a first language different than a second language used to generate the HVL code, the generating including identifying one or more expressions associated with the one or more functional defects in the HVL code;
identify one or more patterns associated with the one or more functional defects in one or more second design code written in the first language;
map the one or more expressions of the HVL code with the one or more identified patterns;
form a bind of the one or more expressions and the one or more patterns based on the mapping, the bind including one or more semantic expressions of a combination of the one or more expressions and the one or more patterns; and
evaluate the bind to identify the one or more functional defects in the design code.

6. The system as claimed in claim 5, wherein the one or more patterns are patterns identified in the one or more second design code using at least a Python framework based on the generated HVL code.

7. The system as claimed in claim 5, wherein, the processing circuitry is further configured to evaluate the bind by:
identifying one or more performance parameters associated with the semantic expressions; and
detecting the one or more functional defects based on the one or more identified performance parameters and one or more threshold performance parameters corresponding to the semantic expression.

8. The system as claimed in claim 7, wherein the one or more threshold performance parameters are calculated using the one or more patterns.

9. A non-transitory computer-readable medium comprising computer-readable instructions recorded thereon, which when executed by processing circuitry, causes the processing circuitry to:
generate Hardware Verification Language (HVL) code representing semantic behaviour of design code, the design code written in a first language different than a second language used to generate the HVL code, the generating including identifying one or more expressions associated with one or more functional defects in the HVL code;
identify one or more patterns associated with the one or more functional defects in one or more second design code written in the first language;
map the one or more expressions of the HVL code with the one or more identified patterns;
form a bind of the one or more expressions with the one or more patterns based on the mapping, the bind including one or more semantic expressions of a combination of the one or more expressions and the one or more patterns; and
evaluate the bind to identify the one or more functional defects in the design code.

10. The non-transitory computer-readable medium as claimed in claim 9, wherein the one or more patterns are identified in the one or more second design code using at least a Python framework based on the generated HVL code.

11. The non-transitory computer-readable medium as claimed in claim 9, wherein the evaluating the bind further comprises:
identifying one or more performance parameters associated with the semantic expressions; and
detecting the one or more functional defects based on the one or more identified performance parameters and one or more threshold performance parameters corresponding to the semantic expressions.

12. The non-transitory computer-readable medium as claimed in claim 9, wherein the one or more threshold performance parameters are calculated using the one or more patterns.
